(19) United States
(12) Patent Application Publication
(10) Pub. No.: US 2013/0334526 A1
(43) Pub. Date: Dec. 19, 2013

(54) THIN FILM TRANSISTOR

(71) Applicant: PANASONIC CORPORATION, Osaka (JP)

(72) Inventors: Eiichi SATOH, Hyogo (JP); Toshiyuki AOYAMA, Osaka (JP)

(73) Assignee: PANASONIC CORPORATION, Osaka (JP)

(21) Appl. No.: 13/973,694

(22) Filed: Aug. 22, 2013

Related U.S. Application Data
(63) Continuation of application No. PCT/JP2012/003978, filed on Jun. 19, 2012.

(30) Foreign Application Priority Data
Jan. 20, 2012 (JP) 2012-009865

(51) Int. Cl. H01L 29/786

(52) U.S. Cl. CPC H01L 29/7869
USPC 257/43

(57) ABSTRACT

A thin film transistor includes a gate electrode formed on a substrate; a gate insulation film covering the gate electrode; an oxide semiconductor layer formed on the gate insulation film; a source electrode and a drain electrode covering an edge portion of the oxide semiconductor layer, and a passivation film covering the source electrode, the drain electrodes, and the oxide semiconductor layer. The passivation film is made of an insulating material, and the insulating material is capable of attenuating a light of wavelength not greater than 450 nm.

### TECHNICAL FIELD

The present disclosure relates to a TFT (Thin Film Transistor) used for LCD (Liquid Crystal Device) displays or OLED (Organic Light Emitting Device) displays.

### BACKGROUND

An oxide semiconductor TFT employs a channel etching stopper in order to prevent oxide semiconductor from being damaged during a formation of a source electrode and a drain electrode.

The patent literature JP2010-161227A1 describes a channel etching stopper made of SiO2 thin film in order to prevent a characteristic change of the oxide semiconductor due to a reducible gas during a formation of the channel etching stopper.

### SUMMARY

The present disclosure relates to a thin film transistor including:

a gate electrode formed on a substrate;

a gate insulation film covering the gate electrode;

an oxide semiconductor layer formed on the gate insulation film;

a source electrode and a drain electrode covering an edge portion of the oxide semiconductor layer, and

a passivation film covering the source electrode, the drain electrodes, and the oxide semiconductor layer.

The passivation film is made of an insulating material capable of attenuating light having a wavelength not greater than 450 nm.

The foregoing structure allows reducing changes in characteristic during the manufacturing of a TFT.

### BRIEF DESCRIPTION OF DRAWINGS

FIG. 1 is a perspective diagram of an EL display according to one embodiment.

FIG. 2 is a perspective diagram illustrating an example of a pixel bank of the EL display.

FIG. 3 is a circuit diagram illustrating a circuit structure of a pixel circuit in a TFT according to one embodiment.

FIG. 4 is a schematic sectional view illustrating the TFT.

FIG. 5A is a schematic sectional view illustrating a manufacturing method of the TFT.

FIG. 5B is a schematic sectional view illustrating the manufacturing method of the TFT.

FIG. 5C is a schematic sectional view illustrating the manufacturing method of the TFT.

FIG. 5D is a schematic sectional view illustrating the manufacturing method of the TFT.

FIG. 5E is a schematic sectional view illustrating the manufacturing method of the TFT.

FIG. 5F is a schematic sectional view illustrating the manufacturing method of the TFT.

FIG. 5G is a schematic sectional view illustrating the manufacturing method of the TFT.

### DETAILED DESCRIPTION

An embodiment of a thin film transistor of the present disclosure will be described hereafter with reference to the accompanying drawings.

### Structure of an OLED display

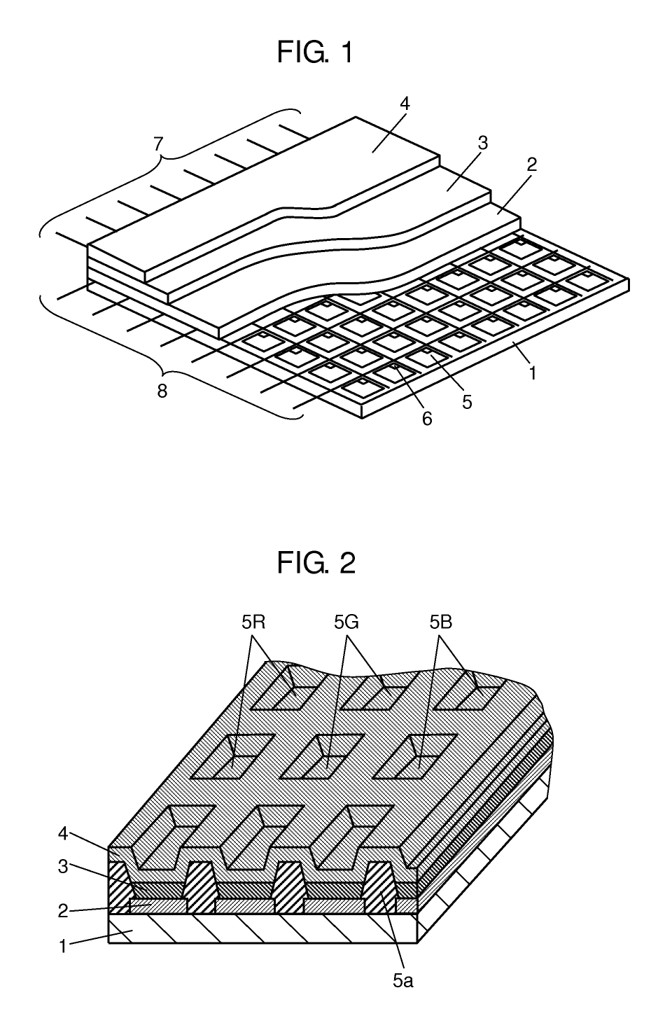

As illustrated in FIGS. 1 to 3, the EL (Electro Luminescence) display comprises: TFT array unit 1, anode 2 (lower electrode), EL (Electro Luminescence) layer 3, cathode 4 (upper electrode) layered in sequence. TFT array unit 1 includes multiple TFT 10 and multiple TFT 11. EL layer 3 is a light emitting layer made of an organic material. Anode 2, EL layer 3, and cathode 4 are collectively called “light emitting unit” hereafter. The light emission from the light emitting unit is controlled by TFT array unit 1.

The light emitting unit has the following structure: EL layer 3 is disposed between a pair of electrodes (anode 2 and cathode 4); a hole-transport layer is layered between anode 2 and EL layer 3, and an electron-transport layer is layered between EL layer 3 and a transparent cathode 4. TFT array unit 1 has multiple pixels 5 which are arranged in matrix.

Each of the pixels 5 is controlled by pixel circuits 6 which are provided in each of the pixels 5. TFT array unit 1 has multiple gate wirings 7, source wirings 8, and power supply wirings 9. Gate wirings 7 are aligned in row. Source wirings 8 function as signal lines and are aligned in column so as to intersect gate wirings 7. Power supply wirings 9 are extended parallel to source wirings 8.

Each of pixel circuits 6 has TFT 10 working as a switching device, and TFT 11 working as a driving device . One gate wiring 7 is connected to multiple gate electrode 10g of TFTs 10 that are aligned in the same row. One source wiring 8 is connected to multiple source electrode 10s of TFTs 10 that are aligned in the same column. One power supply wiring 9 is connected to multiple drain electrode 11d of TFTs 11 that are aligned in the same column.

As illustrated in FIG. 2, each of pixels 5 of the EL display has sub pixels 5R, 5G, and 5B in three colors (red, green, blue) which are formed on the display surface that are arranged into a matrix (sub pixels 5R, 5G, 5B are referred to simply as “sub pixels” hereafter). Each of the sub pixels is separated from each other by bank 5a. Bank 5a is formed by a first group of protrusions parallel to gate wirings 7 and a second group of protrusions parallel to source wirings 8, so that the protrusions of the first and second groups cross each other. Each of the sub pixels is surrounded by bank 5a. In other words, each of the sub pixels is formed in an opening of bank 5a.

Anodes 2 are formed on an interlayer insulation film of TFT array unit 1 and in the openings of bank 5a for every sub pixels . EL layers 3 are formed separately on anodes 2 for every sub pixels. Transparent cathode 4 is formed so as to cover bank 5a and to commonly cover all of the sub pixels and EL layers 3 of the EL display.

TFT array unit 1 has pixel circuits 6 provided for every sub pixels. Each of the sub pixels and each of pixel circuits 6 are electrically connected by a contact hole and a relay electrode.

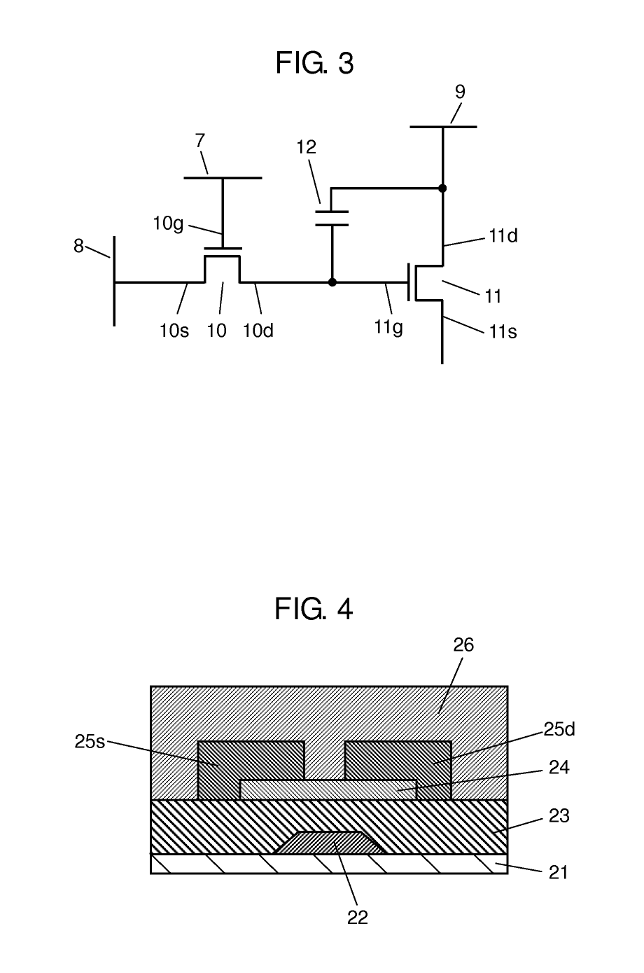

As illustrated in FIG. 3, pixel circuit 6 has TFT 10 working as a switching device, TFT 11 working as a driving device, and capacitor 12 storing data for displaying image.

TFT 10 has gate electrode 10g connected to gate wiring 7; source electrode 10s connected to source wiring 8; drain electrode 10d connected to capacitor 12 and gate electrode 11g of TFT 11, and a semiconductor film. When a voltage is applied to gate wiring 7 and source wiring 8, capacitor 12 charges the voltage applied to source wiring 8 as display data.

TFT 11 has gate electrode 11g connected to drain electrode 10d of TFT 10; drain electrode 11d connected to power supply wiring 9 and capacitor 12; source electrode 11s connected to anode 2, and a semiconductor film. TFT 11 supplies a current, having an amount corresponding to the voltage charged in capacitor 12, from power supply wiring 9 to anode 2 via source electrode 11s.

As discussed above, the EL display according to this embodiment employs an active matrix method that controls the image-displaying for every pixel 5 positioned on the intersections of gate wirings 7 and source wirings 8.

### Structure of a TFT

As illustrated in FIG. 4, TFT 10 (or TFT 11) comprises: gate electrode 22 formed on substrate 21; gate insulation film covering gate electrode 22; an island-like oxide semiconductor layer 24 formed on gate insulation film 23, and source electrode 25s and drain electrode 25d that are formed covering edge portions of oxide semiconductor layer 24.

TFT 10 (or TFT 11) further comprises passivation film 26 formed on source electrodes 25s and drain electrode 25d of TFTs 10 (or TFT 11) so as to cover these electrodes. Passivation film 26 is provided in order to insulate the electrodes 25s and 25d from an electrode of a luminescence layer which is formed as an upper layer of the electrodes 25s and 25d. Passivation film 26 has a contact hole inside thereof for electrically connecting the electrodes 25s (or 25d) and the electrode of the luminescence layer.

Substrate 21 is made of e.g. a glass substrate. Instead, a resin substrate can be used for flexible displays.

Gate electrode 22 can be made of metal, such as titanium, molybdenum, tungsten, aluminum, and gold, or of an electric conduction oxide such as ITO (Indium Tin Oxide) . An alloy such as MoW can be also used as the metal. Gate electrode 22 can be also made of metal having good adhering characteristic to the oxide materials (e.g. a laminated material comprising titanium, aluminum, or gold) in order to improve an adherence to other layers.

Gate insulation film 23 can be made either by a single layer or layered layers of an oxide thin film (e.g. silicon oxide, hafnium oxide), a nitride film (e.g. silicon nitride) or a sioxynitride film.

Oxide semiconductor layer 24 can be made of oxide semiconductor including Indium, Zinc, and Gallium, preferably in an amorphous state. Oxide semiconductor layer 24 can be formed using a DC sputtering method, an RF (Radio Frequency) sputtering method, a plasma CVD method, a pulsed laser deposition method, or an ink-jet printing method. Thickness of oxide semiconductor layer 24 is preferably between 10 to 150 nm. This is because a pinhole may easily generate when the thickness is smaller than 10 nm, and a leakage current during OFF operation or a subthreshold swing value (S value) of the transistor increases when the thickness is larger than 150 nm.

Source electrode 25s and drain electrode 25d can be made of metal (e.g. titanium, molybdenum, tungsten, aluminum, or gold) or electric conducting oxides (e.g. ITO) similarly to gate electrode 22. An alloy such as MoW (molybdenum-tungsten) can be also used as the metal. The electrodes 25s and 25d can be also made of layered metals sandwiching a material which adheres well to the oxide materials (e.g. titanium, aluminum, or gold) to improve an adherence to other layers.

Passivation film 26 can be made of a resin-coated photosensitive insulating material which attenuates a light having a wavelength not greater than 450 nm, such as silsesquioxane, acrylics, or siloxane. Accordingly, light of wavelength not greater than 450 nm is prevented from being irradiated to the channel portion of the oxide semiconductor layer 24. Preferably, passivation film 26 employs a photosensitive insulating material having light transmittance not greater than 20% for the light having a wavelength not greater than 450 nm.

The use of a photosensitive insulating material enables passivation film 26 to be fabricated using photolithography. This omits a fabrication process of dry etching method or a wet etching method and can reduce cost. Passivation film 26 can be also made of a layered structure of an inorganic insulating material (e.g. oxidization silicon, aluminum oxide, or titanium oxide) and a photosensitive insulating material. Passivation film 26 can be fabricated using a CVD method, a sputtering method, or an ALD method.

### Manufacturing Method of TFT

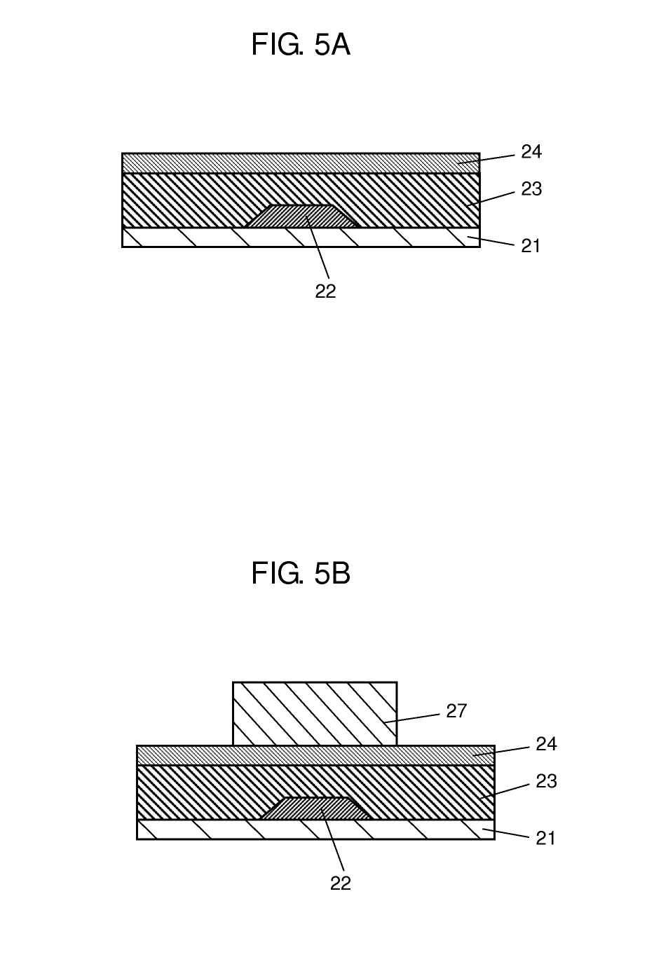

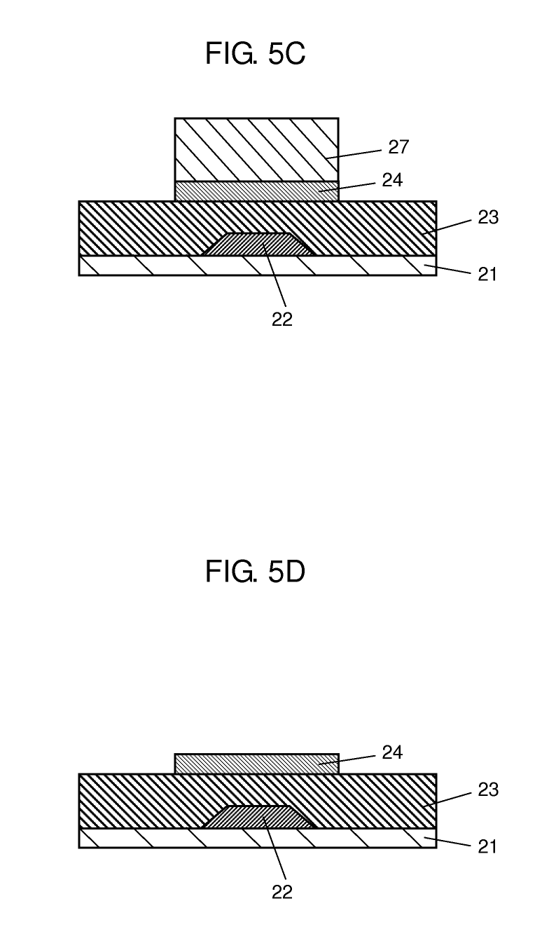

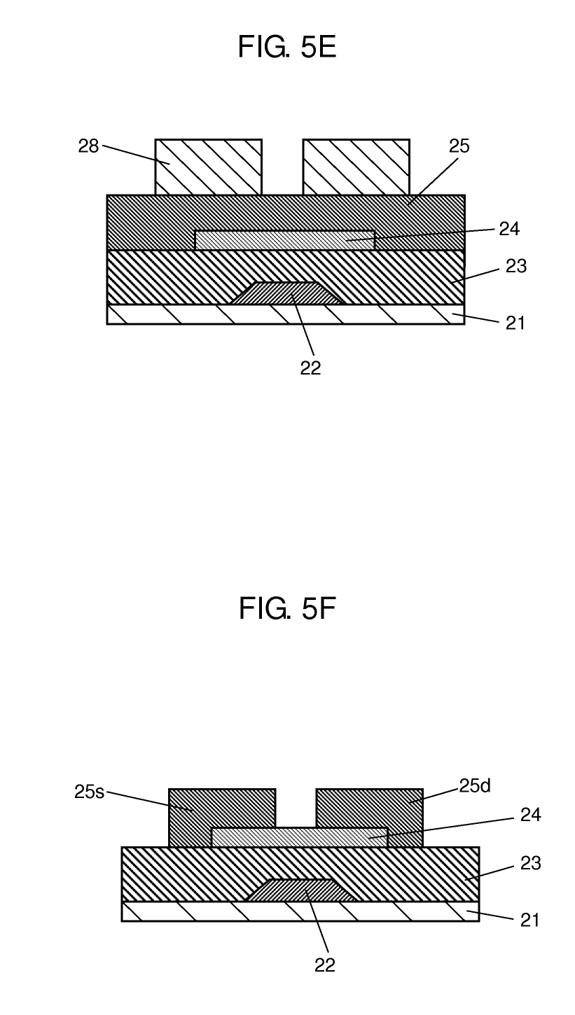

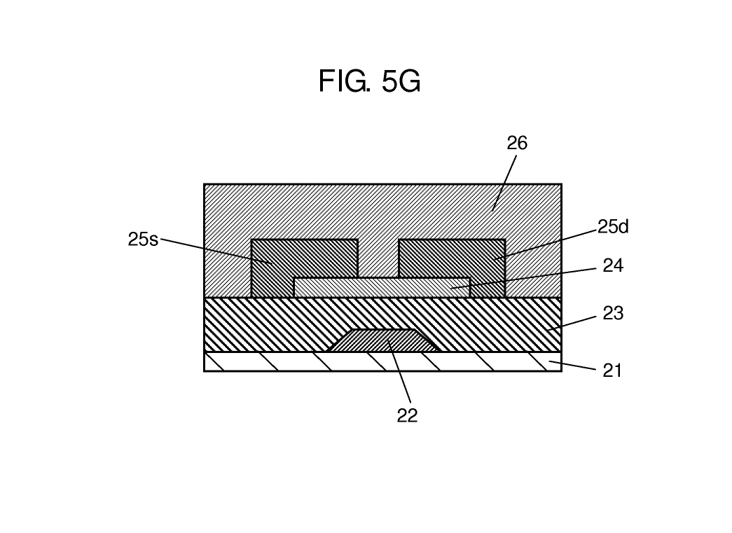

The manufacturing method of the TFT is described with reference to FIGS. 5A to 5G.

(i) As illustrated in FIG. 5A, gate electrode 22 is formed to have a predetermined gate shape on substrate 21; gate insulation film 23 is formed so as to cover gate electrode 22, and oxide semiconductor layer 24 is formed on gate insulation film 23.

(ii) As illustrated in FIG. 5B, resist mask 27 is then formed on oxide semiconductor layer 24.

(iii) As illustrated in FIG. 5C, oxide semiconductor layer 24 is then patterned using resist mask 27. Oxide semiconductor layer 24 can be fabricated by wet etching method which uses oxalic acid, chloride or a mixture of acid (e.g. phosphoric acid, nitric acid, or acetic acid).

(iv) As illustrated in FIG. 5D, resist mask 27 is then removed by wet etching process using resist-removing solution or dry etching process using O2-plasma.

(v) As illustrated in FIG. 5E, an electrode layer 25 which will become source electrode 25s and drain electrode 25d is then formed. Resist mask 28 is formed on the electrode layer thereafter.

(vi) As illustrated in FIG. 5F, source electrode 25s and drain electrode 25d are fabricated from electrode layer 25 by using the resist mask 28 as a pattern on the electrode layer 25. Afterwards, resist mask 28 is removed. These electrodes can be fabricated by wet etching method. Oxide semiconductor layer 24 is then heated for 0.5 to 1200 minutes at temperature between 150 degrees to 450 degrees Celsius. This heating process reduces contact resistances between source electrode 25s and oxide semiconductor layer 24, and between drain electrode 25d and oxide semiconductor layer 24, and further stabilizes the characteristic of oxide semiconductor layer 24.

(vii) As illustrated in FIG. 5G, passivation film 26 is formed. As discussed above, passivation film 26 has contact holes inside to establish electric contacts to source electrode 25s, drain electrode 25d and gate electrode 22. The contact holes can be formed using a photo-lithographic method when passivation film 26 is made of a photosensitive material.

As discussed above, passivation film 26 of the EL display in this embodiment is made of resin-coated photosensitive insulating material that attenuates a light having a wavelength not greater than 450 nm. The channel portion of oxide semiconductor layer 24 is thereby prevented from being irradiated by the light having wavelength not greater than 450 nm, and allows manufacturing oxide semiconductor TFTs 10 (or TFTs 11) with small optical conduction.

The foregoing structure allows reducing changes in characteristic during a formation of a TFT, and provides a desired TFT.

### INDUSTRIAL APPLICABILITY

The present disclosure is useful for stabilizing the characteristics of an oxide semiconductor TFT.

1. A thin film transistor comprising:
a gate electrode formed on a substrate;
a gate insulation film covering the gate electrode;
an oxide semiconductor layer formed on the gate insulation film;
a source electrode and a drain electrode covering an edge portion of the oxide semiconductor layer, and
a passivation film covering the source electrode, the drain electrodes, and the oxide semiconductor layer,
wherein
the passivation film is made of a photosensitive insulating material having light transmittance not greater than 20 percent of light having a wavelength not greater than 450 nm.

2. The thin film transistor of claim 1, wherein
the oxide semiconductor layer is made of oxide semiconductor including Indium, Zinc, and Gallium.
